(19) United States
(12) Patent Application Publication
(10) Pub. No.: US 2011/0048490 A1
(43) Pub. Date: Mar. 3, 2011

(54) LATTICE-MATCHED CHALCOGENIDE MULTI-JUNCTION PHOTOVOLTAIC CELL

(76) Inventors: Mark T. Bernius, Midland, MI (US); Beth M. Nichols, Midland, MI (US); Robert P. Haley, Midland, MI (US)

(21) Appl. No.: 12/806,190

(22) Filed: Jul. 29, 2010

Related U.S. Application Data
(60) Provisional application No. 61/230,190, filed on Jul. 31, 2009.

(51) Int. Cl. H01L 31/042; H01L 31/18; H01L 31/032

(52) U.S. Cl. 136/244; 438/74; 257/E31.027; 257/E31.001

(57) ABSTRACT

A multi junction photovoltaic device is disclosed. In certain examples, the device includes an upper photovoltaic cell comprising a first plurality of layers of films, including a first active layer of a chalcogenide having a first lattice constant and first energy band gap, and a lower photovoltaic cell disposed below the upper photovoltaic cell and adapted to receive photon radiation passing through the upper photovoltaic cell, and comprising a second plurality of layers of films, including an active second layer of a IB-IIIA-chalcogenide having a second lattice constant and a second energy band gap. The first lattice constant differs from the second lattice constant by no more than about 10%. The first energy band gap can be greater than the second energy band gap by at least about 0.5 eV, or 0.6 eV, or 0.7 eV.

### CROSS-REFERENCE TO RELATED APPLICATIONS

This application claims the benefit of U.S. Provisional Application Ser. No. 61/230,190, filed Jul. 31, 2009; which application is incorporated herein by reference.

### BACKGROUND

Non-polluting sources of energy are actively being sought as a replacement for the burning of fossil fuels. The generation of energy from solar radiation is one type of clean energy that is receiving significant attention. Solar energy collectors, such as photovoltaic cells (also referred to as “solar cells”), may be used to generate energy where and when there is adequate sunlight.

Solar energy is distributed in a range of frequencies, or photons of a range of energies. Photovoltaic cells having a single energy band gap convert a limited portion of the solar energy they receive into electricity. Considerable efforts have been devoted to designing multi junction photovoltaic cells that capture a wider range of photon energies to achieve high efficiencies.

### SUMMARY

This disclosure describes devices and methods in which a multi-junction photovoltaic device is configured such that the absorber layers in the respective photovoltaic cells have different energy band gaps but similar lattice constants.

In one aspect, the disclosure describes a multi-junction photovoltaic device that includes (a) an upper photovoltaic cell comprising a first plurality of layers of films, including a first active layer of a chalcogenide having a first lattice constant and first energy band gap, and (b) a lower photovoltaic cell disposed below the upper photovoltaic cell and adapted to receive photon radiation passing through the upper photovoltaic cell, and comprising a second plurality of layers of films, including an active second layer of a IB-IIIA-chalcogenide having a second lattice constant and a second energy band gap, where the first lattice constant being different from the second lattice constant by no more than about 10%.

In a second aspect the disclosure describes a multi-junction photovoltaic device, comprising: an upper photovoltaic cell comprising a first plurality of layers of films, including a first active layer of a first IA-IIIB chalcogenide having a first lattice

constant and first energy band gap; a lower photovoltaic cell disposed below the upper photovoltaic cell and adapted to receive photon radiation passing through the upper photovoltaic cell, and comprising a second plurality of layers of films, including an active second layer of a second IB-IIIA-chalcogenide having a second lattice constant and a second energy band gap; and a third layer of film one or more intervening layers each of which has a lattice constant and is disposed between the first layer of IB-IIIA chalcogenide and second layer of IB-IIIA-chalcogenide, wherein the third layer having a third lattice constant the lattice constants of adjacent layers differing from the second differ lattice constants by no more than about 10%.

As used in this specification, a layer or material is “active” if it participates electrically in a photovoltaic device. Examples of active layers include buffer layers, absorber layers, tunnel junction layers, electrical contact layers (e.g. back contacts and transparent electrical contact layers. Examples of non-active, or passive, layers include glass or polymeric encapsulating layers disposed on top of solar cells to shield the internal structures of the solar cells from the environment but not otherwise contributing electrically to the operations of the solar cells.

In another aspect, the first energy band gap differs from (preferably is greater than) the second energy band gap by at least about 0.5 eV, or 0.6 eV, or 0.7 eV.

Thus, according to one preferred embodiment, one layer (preferably the second layer) of IB-IIIA-chalcogenide can be a copper indium selenide, copper indium gallium selenide, copper indium sulfide, copper indium gallium sulfide, copper indium sulfide selenide, or copper indium gallium sulfide selenide, or a combination thereof. These compounds can also be represented by the formula CuIn₍₁₋ₓ₎GaₓSe_{(2-y)}S_{y} where x is 0 to 1 and y is 0 to 2 (referred to herein as CIGSS). The other layer, preferably the first layer, of IB-IIIA-chalcogenide comprises a Ag-chalcogenide, Ag-IIIB-chalcogenide or copper gallium selenide, copper gallium sulfide or copper gallium selenide sulfide, or a combination thereof. Examples include Ag₂Se, AgInSe₂, AgGaSe₂, CuGaSe₂, or a combination thereof.

In another aspect, the first layer of chalcogenide is a product of metal co-evaporation, metal (e.g. copper, silver, indium, gallium, or combinations thereof) evaporation with in-situ post-selenization, or metal (e.g. copper, silver, indium, gallium, or combinations thereof) sputtering with ex situ post-selenization.

In another aspect, the multi-junction photovoltaic device described above further comprises one or more intervening layers of film disposed between the first layer of chalcogenide and second layer of IB-IIIA-chalcogenide, each of the intervening layers having a lattice constant different from the second lattice constant by no more than about 10%. Furthermore, the first layer, second layer and intervening layers can be epitaxial with each other.

In a further aspect, a method of making a photovoltaic device is described, the method comprising (a) selecting a first, IB-IIIA-chalcogenide material having a first lattice constant and first energy band gap, (b) selecting a second, chalcogenide material having a second lattice constant and second energy band gap, the second lattice constant being different from the second lattice constant by no more than about 10%, (c) forming a lower photovoltaic cell comprising a first layer comprising the IB-IIIA-chalcogenide, and (d) forming an upper photovoltaic cell comprising a second layer comprising the chalcogenide above the lower photovoltaic cell such that the lower photovoltaic cell is disposed to receive photon radiation passing through the upper photovoltaic cell. More specific choices of materials for forming the layers of the photovoltaic cells can be made as described above.

In another aspect, the steps of forming the upper and lower photovoltaic cells and forming the plurality of layer of films are carried out such that the first and second layers and the plurality of layers of films are epitaxial with each other.

In a further aspect, the step of forming the upper photovoltaic cell comprises forming the second layer metal co-evaporation, metal evaporation with in-situ selenization, or metal sputtering with ex situ post-selenization, wherein the metal comprises copper, silver, indium, gallium, or a combination thereof.

These and various other features as well as advantages will be apparent from a reading of the entire specification, including the following detailed description and associated drawings. Additional features are set forth in the description that follows and, in part, will be apparent from the description, or may be learned by practice of the described examples. The benefits and features will be realized and attained by the structure particularly pointed out in the written description and claims hereof as well as the appended drawings.

It is to be understood that both the foregoing general description and the following detailed description are exemplary and explanatory and are intended to provide further explanation of the invention as claimed.

### BRIEF DESCRIPTION OF THE DRAWINGS

The following drawing figures are illustrative of examples of systems and methods described below and are not meant to limit the scope of the disclosure in any manner, which scope shall be based on the claims appended hereto.

FIG. 1 schematically illustrates a multi junction photovoltaic device according to one aspect of the present disclosure.

FIG. 2 schematically illustrates a multi junction photovoltaic device according to another aspect of the present disclosure.

### DETAILED DESCRIPTION OF ILLUSTRATIVE EXAMPLES

This disclosure describes devices and methods in which a multi junction photovoltaic device is configured such that the absorber layers in the respective photovoltaic cells have different energy band gaps but similar lattice constants. One of the advantages of certain examples is that the electrical or mechanical properties, or both, of the device can be improved over the conventional multi-junction photovoltaic cells because of the substantially matched crystal structures of the various layers within the device.

The following description of various examples is merely illustrative in nature and is in no way intended to limit the disclosure. While various examples are described for purposes of this specification, and various changes and modifications may be made which will readily suggest themselves to those skilled in the art, and which may be encompassed by the claims.

Photovoltaic (“PV”) cells are solar energy collectors that convert solar radiation (sunlight) into electricity. Various types of photovoltaic cells are known. For example, thin-film, polycrystalline, heterojunction photovoltaic (solar) cells are known. Another example of PV cells is a chalcogenide-based thin-film PV cell. One particularly useful type of chalcogenide-based thin-film PV cell employs a selenized copper compound such as copper indium selenides (“CIS”), or gallium-substituted copper indium selenides (“CIGS”) or CIGSS as the absorber material. In one type of PV cells, for example, the cell has the following layers in order molybdenum (Mo), a CIGSS layer, cadmium sulfide (CdS), preferably an intrinsic Zinc oxide layer (iZnO), and aluminum-doped zinc oxide (“AZO”). The cell may be constructed by sequential deposition of the thin film layers. In this example, CdS is used as the buffer layer and AZO is used as the top transparent conductive oxide front contact. Photo-conversion is accomplished with the absorption of electromagnetic radiation in the top-most regions of the chalcogenide material and the efficient production of electron-hole pairs and their collection by the p-n junction formed between the chalcogenide and the buffer layer materials (e.g. cadmium sulfide, zinc sulfide, indium sulfide, indium selenide, cadmium selenide, zinc selenide, zinc indium selenide, indium oxide and cadmium oxide).

In a photovoltaic device having a single photovoltaic cell, incident photons with energies below the band gap of the absorber layer do not generate electron-hole pairs, hence electricity, and either pass through the material undisturbed or are scattered within the material to generate heat. Photons with energies above the band gap of the absorber material do excite electron-hole pairs, which become useful electrical output. However, the excess photon energy also results in scattering within the material, thereby generating heat, which is then lost. These losses limit the useful output of PV cells. To improve photovoltaic conversion efficiencies, multi-junction solar cells can be constructed. Such cells are typically composed of several layers of material that have different band gaps. The top layer has the largest band gap while the bottom layer has the smallest band gap. This design allows less energetic photons to pass through the upper layer(s) and be absorbed by a lower layer, resulting in an increase in the overall efficiency of the PV device.

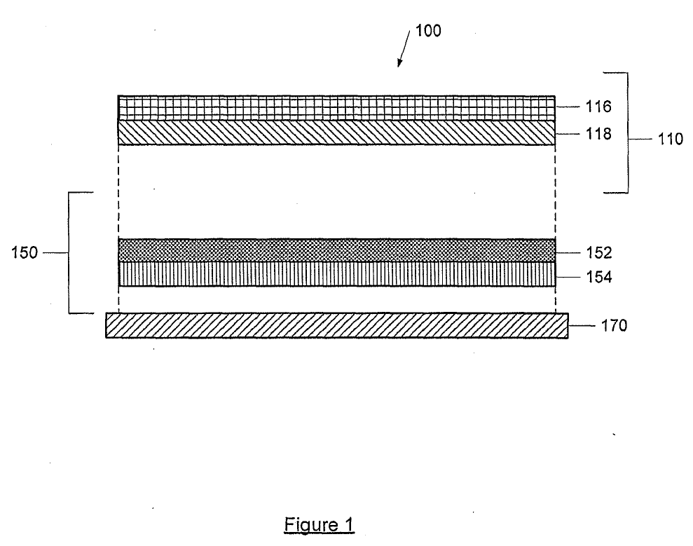

Typically each of the plurality of layers will include at least an absorber and buffer layers and may include additional layer such as transparent conductive oxide layers. Referring to FIG. 1, in one aspect of the present disclosure, a multi-junction photovoltaic device 100 includes (a) an upper photovoltaic cell 110 that has a first plurality of layers of films, including a first active layer 118 of a chalcogenide having a first lattice constant and first energy band gap, and (b) a lower photovoltaic cell 150 disposed below the upper photovoltaic cell which receives photon radiation passing through the upper photovoltaic cell. The lower cell has a second plurality of layers of films, including an active second layer 154 of a IB-IIIA-chalcogenide having a second lattice constant and a second energy band gap. The first lattice constant and the second lattice constant differ by no more than about 10%, preferably no more than 5%, more preferably no more than 2%.

In this illustrative example, the upper cell 110 further includes a buffer layer 116, and the lower cell 150 further includes a buffer layer 152. The lower cell 150 is disposed on a substrate 170, which may also function as an electrode of the lower cell 150 and can be either rigid or flexible.

In another aspect, there can be one or more intervening layers between the two active layers (118 and 154, respectively, in the example above). The intervening layer or layers can have lattice constant or constants that are different from the first lattice constant or second lattice constant, or both. In certain configurations, it can be advantageous to have the lattice constant or constants of the intervening layer or layers closely matched to the respective adjacent active layers. In that event, adjacent layers preferably have lattice constants differing from each other by no more than 10%, preferably no more than 5%, more preferably no more than 2%. This is particularly preferred if an intervening layer has a thickness greater than 2 nm, more preferably greater than 5 nm, more preferably still greater than 10 nm, yet more preferably greater than 20 nm, and most preferably greater than 30 nm. In one example, where an layer intervening the first and second active layers is more than about 10, 25 or 50 nm thick, the lattice constant of the intervening layer differs from the second lattice constant by no more than 10%, preferably no more than 5%, more preferably no more than 2%. The lattice constant of the intervening layer can also differ from the first lattice constant by no more than 10%, preferably no more than 5%, more preferably no more than 2%. In another example, a plurality of intervening layers include a first one of the intervening layer is adjacent the first active layer and a second one of the intervening layers is adjacent the second active layer. The lattice constant of the first intervening layer differs from the lattice constant of the first active layer by no more than 10%, preferably no more than 5%, more preferably no more than 2%, and the lattice constant of the second intervening layer differs from the lattice constant of the second active layer by no more than 10%, preferably no more than 5%, more preferably no more than 2%. Either or both of the first and second intervening layers can be more than about 10, 25 or 50 nm thick. In these examples, the lattice constants of the first and second actively layers can differ by more or less than about 10%, preferably no more than 5%, more preferably no more than 2%.

The photon absorption property of the upper cell portion 110 is characterized by the band gap of the absorber layer 118 of the upper sub-cell. Thus, the upper cell is adapted to absorb photons having energy levels equal to greater than the band gap of the absorber layer 118 and to transmit the photons with lower energy levels. The lower cell 150, which is characterized by the smaller band gap of its absorber layer (in one example layer 154), then receives the photons passing through the upper photovoltaic cell 110. In one aspect of the disclosure, the first energy band gap can be greater than the second energy band gap by at least about 0.5 eV. In further examples, the first energy band gap can be greater than the second energy band gap by at least about 0.6 eV or 0.8 eV.

In another aspect, the second layer 154 of IB-IIIA-chalcogenide can be a copper indium selenide, copper indium gallium selenide, copper indium sulfide, copper indium gallium sulfide, copper indium sulfide selenide, or copper indium gallium sulfide selenide, or a combination thereof. These compounds can also be represented by the formula CuIn₍₁₋ₓ₎GaxSe_{(2-y)}S_{y} where x is 0 to 1 and y is 0 to 2. For example, layer 118 can be an absorber layer comprising a IB-IIIA-chalcogenide such as copper indium selenide (CIS) or copper indium gallium selenide (CIGS) in this illustrative example. The energy band gap is about 1.1 eV for CIS, and about 1.2 eV for CIGS. The lattice constants are about a=5.47-5.86 Å; b=5.47-5.86 Å; c=5.47-11.73 Å for CIS and about a=5.44-5.74 Å; b=5.44-5.74 Å; c=5.44-11.36 Å for CIGS.

In another aspect, the first layer 118 of IB-IIIA-chalcogenide comprises a Ag-chalcogenide, Ag-IIIB-chalcogenide or copper gallium selenide, copper gallium sulfide or copper gallium selenide sulfide, or a combination thereof. Examples include Ag₂Se, AgInSe₂, AgGaSe₂, CuGaSe₂ or a combination thereof. The energy band gap range from about 1.1 eV to 1.8 eV for Ag₂Se and its related ternary compounds (including AgInSe₂, for which the band gap is about 1.2 to 1.5 eV) incorporating elements such as indium, gallium and germanium, and about 1.75 to 1.81 eV for AgGaSe₂. The energy band gap is about 1.7 eV for CuGaSe₂. The lattice constant is about a=5.67-5.99 Å; b=5.67-5.99 Å; c=5.67-11.02 Å for AgGaSe₂ and about a=5.6-6.10 Å; b=5.6-6.10 Å; c=5.6-11.69 Å for AgInSe₂. and a=5.41-5.61 Å; b=5.41-5.61 Å; c=5.41-10.99 Å for CuGaSe₂.

The substrate 170 can be made of any material suitable for constructing PV cell substrates. Examples include glass, polymers, ceramic materials (provided there are back electrical contacts provided in conjunction with such glass, polymer or ceramic materials) and metals. In certain examples, the substrate layer 170 is made of a conductive material, such as a molybdenum foil. In such cases, the substrate layer 170 can function both as a support for the PV cell and an electrical contact layer, and a separate contact layer for the bottom cell portion (such as the lower cell portion 150 in a two junction PV cell can be omitted.

In another aspect, the multi-junction photovoltaic device described above further comprises one or more intervening layers of film disposed between the first layer of chalcogenide and second layer of IB-IIIA-chalcogenide, each of the intervening layers having a lattice constant different from the second lattice constant by no more than about 10%. Furthermore, the first layer, second layer and intervening layers can be epitaxial with each other.

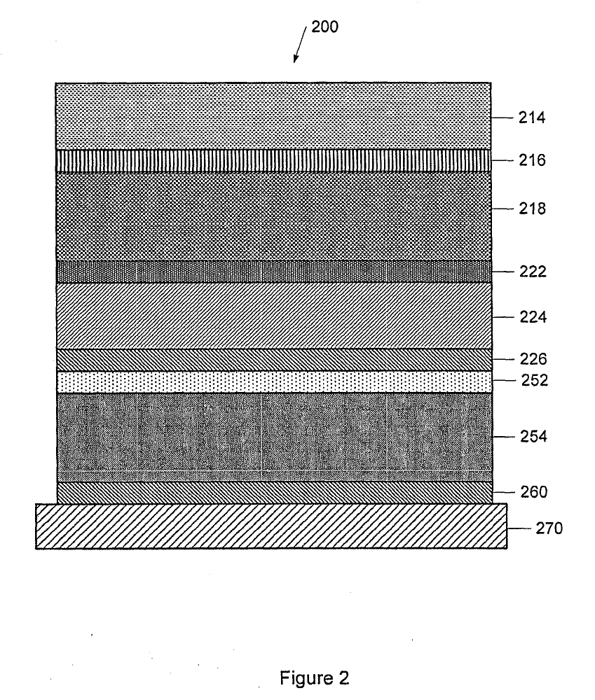

Thus, as illustrated in FIG. 2, in this illustrative example the multi junction PV cell 200 comprises the following layers in sequence, from the substrate up:
a substrate 270 (a rigid or flexible substrate, for example glass, polymer, ceramic, semiconducting, or metal based);
a metallic and electrical back contact 260, for example, molybdenum (which can also be the same as 270);
a p-type absorber material 254, for example, a chalcogenide such as copper indium selenide, copper indium gallium selenide or copper gallium selenide (however, other p-type absorbers besides chalcogenides may be used instead);
an n-type junction emitter, or buffer, layer 252, such as cadmium sulfide, zinc sulfide, indium sulfide, indium selenide, cadmium selenide, zinc selenide, zinc indium selenide, indium oxide and cadmium oxide;
an insulating portion of the “window layer” 226, for example, an oxide of Zn, In, Cd, Sn;
a transparent conductive material 224 such as fluorine-doped tin oxide, tin oxide, indium oxide, ITO, AZO and zinc oxide;
an insulating portion of the “window layer” 222, for example, an oxide of Zn, In, Cd, Sn, etc;
a p-type wide band gap (i.e., with a higher energy band gap than layer 254) absorber chalcogenide material 218 such as Ag-chalcogenide, Ag-IIIB-chalcogenide or copper gallium selenide, or a combination thereof;
an n-type emitter, or buffer, material 216 such as cadmium sulfide, zinc sulfide, indium sulfide, indium selenide, cadmium selenide, zinc selenide, zinc indium selenide, indium oxide and cadmium oxide;
a front side transparent electrical contact 214, for example, a TCO such as indium-tin oxide.

In one aspect of the disclosure, each of the two absorber layers 218 and 254 and the intervening layers, i.e., the buffer layer 252, window layers 226 and 222, and transparent conductive layer 224, can be epitaxial with one or both of its neighboring layers. Of course, the intervening layers can be of other types and configuration, as appropriate.

In another aspect, either or both of the absorber layers can be made by a variety of methods, including, for example, metal co-evaporation, metal (e.g. silver or copper or indium or gallium or combinations thereof) evaporation with in-situ selenization, or metal (e.g. silver or copper or indium or gallium combinations thereof) sputtering with ex situ post-selenization. See, e.g., Zhu, S. F. et.al, Materials Chemistry and Physics, vol. 46, p. 100-102, which in incorporated herein by reference.

In a further aspect of the disclosure, the sequence of the various layers in a multi-junction PV device, such as the one shown in FIGS. 1 and 2, can be altered as appropriate. For example, the relative positions of the buffer layer 116 or 118 and the absorber layer 218 or 254, respectively, can be reversed. In that case, the upper and lower photovoltaic cells have opposite polarities from each other, i.e., the n-type side of the pn junction (such as CdS layers) of the two sub-cells are disposed between the p-type side of the pn junction (such as IB-IIIA-chalcogenide layers) of the photovoltaic cells, or vice versa. The upper and lower cells are therefore connected in parallel and thus capable of supplying a larger current than single-junction cells or conventional multi-junction PV cells. Given a set of materials used for each layer, this configuration can also have the advantage that the layers that are more prone to degradation due environmental conditions (such as moisture and oxygen) may be positioned deeper within the device than the layers more robust against such conditions. See, for example, U.S. Provisional Patent Application Ser. No. 61/149,123, which is hereby incorporated by reference.

In a further aspect, a method of making a photovoltaic device is described, the method comprising (a) selecting a first, IB-IIIA-chalcogenide material having a first lattice constant and first energy band gap, (b) selecting a second, chalcogenide material having a second lattice constant and second energy band gap, the second lattice constant being different from the second lattice constant by no more than about 10%, (c) forming a lower photovoltaic cell comprising a first layer comprising the IB-IIIA-chalcogenide, and (d) forming an upper photovoltaic cell comprising a second layer comprising the IB-IIIA chalcogenide above the lower photovoltaic cell such that the lower photovoltaic cell is disposed to receive photon radiation passing through the upper photovoltaic cell. More specific choices of materials for forming the layers of the photovoltaic cells can be made as described above. Furthermore, the steps of forming the upper and lower photovoltaic cells and forming the plurality of layer of films are carried out such that the first and second layers and the plurality of layer of films are epitaxial with each other.

With at least certain of the above examples, the substantially lattice-matched structures between the buffer layers and intervening layers can result in lower levels of interfacial stress and defect concentration between the layers as compared to non-lattice-matched structures. Physical properties, including electrical and mechanical properties, of the exemplary devices described above are therefore expected to be different from, and often more desirable than, conventional multi-junction PV cells.

Those skilled in the art will recognize that the methods and devices of the present disclosure may be implemented in many manners and as such are not to be limited by the foregoing examples. Moreover, the scope of the present disclosure covers conventionally known manners for carrying out the described features and functions, as well as those variations and modifications that may be made to the materials and shapes of the components described herein as would be understood by those skilled in the art now and hereafter.

While various examples have been described for purposes of this disclosure, such examples should not be deemed to limit the teaching of this disclosure to those examples. Various changes and modifications may be made to the elements and operations described above to obtain a result that remains within the scope of the systems and processes described in this disclosure. Numerous other changes may be made that will readily suggest themselves to those skilled in the art and which are encompassed in the spirit of the invention disclosed and as defined in the appended claims.

We claim:

1. A multi junction photovoltaic device, comprising:
an upper photovoltaic cell comprising a first plurality of layers of films, including a first active layer of a IB-IIIA chalcogenide having a first lattice constant and first energy band gap; and
a lower photovoltaic cell disposed below the upper photovoltaic cell and adapted to receive photon radiation passing through the upper photovoltaic cell, and comprising a second plurality of layers of films, including an active second layer of a IB-IIIA-chalcogenide having a second lattice constant and a second energy band gap,
the first lattice constant being different from the second lattice constant by no more than about 10%.

2. The multi-junction photovoltaic device of claim 1, wherein the first energy band gap is greater than the second energy band gap by at least about 0.5 eV.

3. The multi-junction photovoltaic device of claim 2, wherein the second layer of IB-IIIA-chalcogenide comprises a copper indium selenide, copper indium gallium selenide, copper indium sulfide, copper indium gallium sulfide, copper indium sulfide selenide, or copper indium gallium sulfide selenide, or a combination thereof.

4. The multi-junction photovoltaic device of claim 3, wherein the first layer of IB-IIIA-chalcogenide comprises a Ag-chalcogenide, Ag-IIIB-chalcogenide or copper gallium selenide, copper gallium sulfide or copper gallium selenide sulfide, or a combination thereof.

5. The multi-junction photovoltaic device of claim 4, wherein the second layer of IB-IIIA-chalcogenide comprises a Ag-chalcogenide or Ag-IIIB-chalcogenide, or a combination there of.

6. The multi-junction photovoltaic device of claim 5, wherein the layer of IB-IIIA-chalcogenide comprises Ag₂Se, AgInSe₂, AgGaSe₂, or a combination thereof.

7. The multi-junction photovoltaic device of claim 3, wherein the first layer of chalcogenide is a product of metal co-evaporation, metal evaporation with in-situ selenization, or metal sputtering with ex situ post-selenization, wherein the metal comprises copper, silver, indium, gallium, or a combination thereof.

8. The multi junction photovoltaic device of claim 1, further comprising a third layer of film disposed between the first layer of chalcogenide and second layer of IB-IIIA-chalcogenide, the third layer having a third lattice constant different from the second lattice constant by no more than about 10%.

9. The multi junction photovoltaic device of claim 1, further comprising a plurality of intervening layers of films between the first layer of chalcogenide and second layer of IB-IIIA-chalcogenide, the plurality of intervening layers having respective lattice constants different from the second lattice constant by no more than about 10%.

10. The multi-junction photovoltaic device of claim 9, wherein the first layer, second layer and plurality of intervening layers are epitaxial with each other.

11. The multi junction photovoltaic device of claim 1, wherein the first lattice constant differs from the second lattice constant by no more than about 5%.

12. A method of making a photovoltaic device, the method comprising:
selecting a first, IB-IIIA-chalcogenide material having a first lattice constant and first energy band gap;
selecting a second, IB-IIIA chalcogenide material having a second lattice constant and second energy band gap, the second lattice constant being different from the second lattice constant by no more than about 10%;
forming a lower photovoltaic cell comprising a first layer comprising the first IB-IIIA-chalcogenide; and
forming an upper photovoltaic cell comprising a second layer comprising the second IB-IIIA chalcogenide above the lower photovoltaic cell such that the lower photovoltaic cell is disposed to receive photon radiation passing through the upper photovoltaic cell.

13. The method of claim 12, wherein the step of selecting the first IB-IIIA-chalcogenide comprises selecting CuInSe₂ or Cu(In, Ga)Se₂, or a combination thereof.

14. The method of claim 12, wherein the step of selecting the second chalcogenide comprises selecting a Ag-chalcogenide, Ag-IIIB-chalcogenide or CuGaSe₂, or a combination thereof.

15. The method of claim 14, wherein the step of selecting a chalcogenide comprises selecting AgSe₂ or AgInSe₂, or a combination thereof.

16. The method of claim 12, further comprising:
selecting a third material having a lattice constant not different from the first lattice constant by more than about 10%; and
forming a layer of film between the first and second layers.

17. The method of claim 12, wherein:
the step of selecting a third material comprises selecting a plurality of types of materials, all having respective lattice constants not different from the first lattice constant by more than about 10%; and
the step of forming a layer of film between the chalcogenide and IB-IIIA-chalcogenide layers comprises forming a plurality of layers of films using the plurality of types of materials.

18. The method of claim 17, wherein the steps of forming the upper and lower photovoltaic cells and forming the plurality of layer of films are carried out such that the first and second layers and the plurality of layer of films are epitaxial with each other.

19. A multi-junction photovoltaic device, comprising:
an upper photovoltaic cell comprising a first plurality of layers of films, including a first active layer of a first IA-IIIB chalcogenide having a first lattice constant and first energy band gap;
a lower photovoltaic cell disposed below the upper photovoltaic cell and adapted to receive photon radiation passing through the upper photovoltaic cell, and comprising a second plurality of layers of films, including an active second layer of a second IB-IIIA-chalcogenide having a second lattice constant and a second energy band gap; and
one or more intervening layers each of which has a lattice constant and is disposed between the first layer of IB-IIIA chalcogenide and second layer of IB-IIIA-chalcogenide, wherein the lattice constants of adjacent layers differ by no more than about 10%.

20. The multi-junction photovoltaic device of claim 19, wherein the intervening layer has a thickness of at least about 2 nm.
